(19) United States
(12) Patent Application Publication
(10) Pub. No.: US 2003/0089995 A1
(43) Pub. Date: May 15, 2003

(54) Solid state power amplifying device

(76) Inventors: Douglas M. Macheel, San Jose, CA (US); Lee B. Max, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/292,769

(22) Filed: Nov. 12, 2002

Related U.S. Application Data
(62) Division of application No. 09/952,588, filed on Sep. 13, 2001.
Application No. 09/952,588 is a division of application No. 09/610,790, filed on Jul. 6, 2000, now abandoned.

(51) Int. Cl. H01L 23/48

(52) U.S. Cl. 257/767

(57) ABSTRACT

According to one embodiment, a solid state amplifying device is disclosed. The amplifying device comprises a first input bond pad and a first input connection bonded to the first input bond pad. The amplifying device also includes a second input bond pad and a second input connection bonded to the second input bond pad. An equivalent magnitude of current is supplied to the first and second input bond pads.

### CROSS REFERENCE TO RELATED APPLICATIONS

This application is a divisional application of prior application Ser. No. 09/952,588, filed Sep. 13, 2001 and entitled “A Solid State Power Amplifying Device” which is a divisional of prior application Ser. No. 09/610,790 filed Jul. 6, 2000 and entitled “A Solid State Power Amplifying Device” both of which are assigned to the assignee of the present application.

### FIELD OF THE INVENTION

This invention relates generally to the field of solid-state power amplifying devices including, but not limited to, laterally diffused metal oxide silicon (LDMOS), vertically diffused (DMOS) FETs, metal semiconductor (MESFETs), static induction transistors (SITs), pseudomorphic high electron mobility field effect transistor (PHEMT FETs), bipolar junction transistors (BjTs) and heterojunction bipolar transistors (HBTs).

### BACKGROUND

It is widely known that balancing the output current distribution within the die of a solid-state, power amplifying devices results in performance improvement of gain, efficiency, peak output power and linearity of the devices. An area of amplifier performance enhancement that has heretofore been overlooked is the utilization and optimization of device packaging techniques to assist in balancing the output current distribution within the die of the power amplifying device. Therefore, a method of balancing a solid state, power amplifying device is desired.

### SUMMARY

According to one embodiment, a method of configuring a packaged solid state power amplifying device is disclosed. The method includes applying one or more techniques to enhance the balance of the output current of the amplifying device.

### BRIEF DESCRIPTION OF THE DRAWINGS

A better understanding of the present invention can be obtained from the following detailed description in conjunction with the following drawings, in which:

FIG. 1 is a block diagram of one embodiment of a radio frequency power amplification circuit;

FIG. 2 is a diagram of a typical packaged power amplifying device;

FIG. 3 is a diagram of one embodiment of a packaged power amplifying device;

FIG. 4 is a diagram of another embodiment of a packaged power amplifying device;

FIG. 5 is a diagram of another embodiment of a packaged power amplifying device;

FIG. 6 is a diagram of another embodiment of a packaged power amplifying device;

FIG. 7 is a diagram of another embodiment of a packaged power amplifying device; and

FIG. 8 is a diagram of another embodiment of a packaged power amplifying device.

### DETAILED DESCRIPTION

In the following description, numerous details are set forth. It will be apparent, however, to one skilled in the art, that the present invention may be practiced without these specific details. In other instances, well-known structures and devices are shown in block diagram form, rather than in detail, in order to avoid obscuring the present invention.

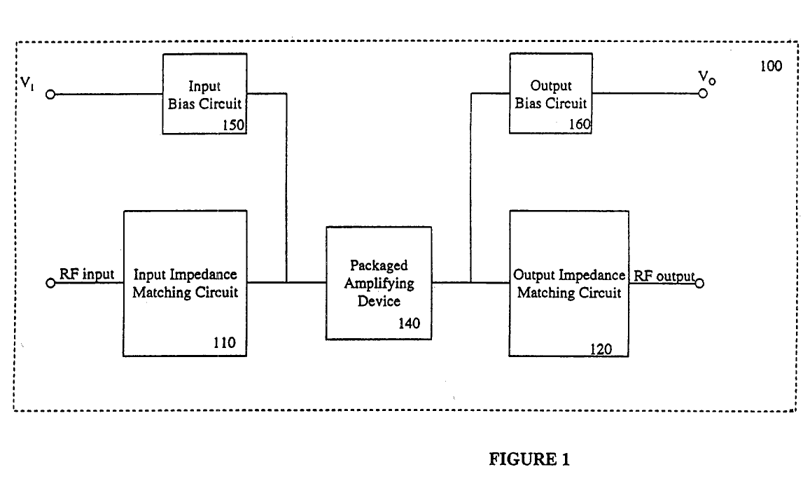

FIG. 1 is a block diagram of one embodiment of a radio frequency amplification circuit 100. Circuit 100 includes an input impedance matching circuit 110, an output impedance matching circuit 120, a packaged amplifying device 140, a bias circuit 150 and a bias circuit 160. According to one embodiment, circuit 100 receives input RF signals at input impedance matching circuit 110, amplifies the signal and transmits the amplified signal from output impedance matching circuit 120 to a load (not shown).

### Packaged Amplifying Device

Packaged device 140 is coupled between input impedance matching circuit 110 and output impedance matching circuit 120. Device 140 amplifies RF signals. According to one embodiment, device 140 comprises a solid state amplifying transistor such as a laterally diffused MOS (LDMOS) transistor. In other embodiments, device 140 may comprise a vertically DMOS. However, one of ordinary skill in the art will appreciate that device 140 may be implemented with other solid state amplifying transistors (e.g., metal semiconductor (MESFETs), static induction transistors (SITs), bipolar junction transistors (BjTs), heterojunction bipolar transistors (HBTs), etc.).

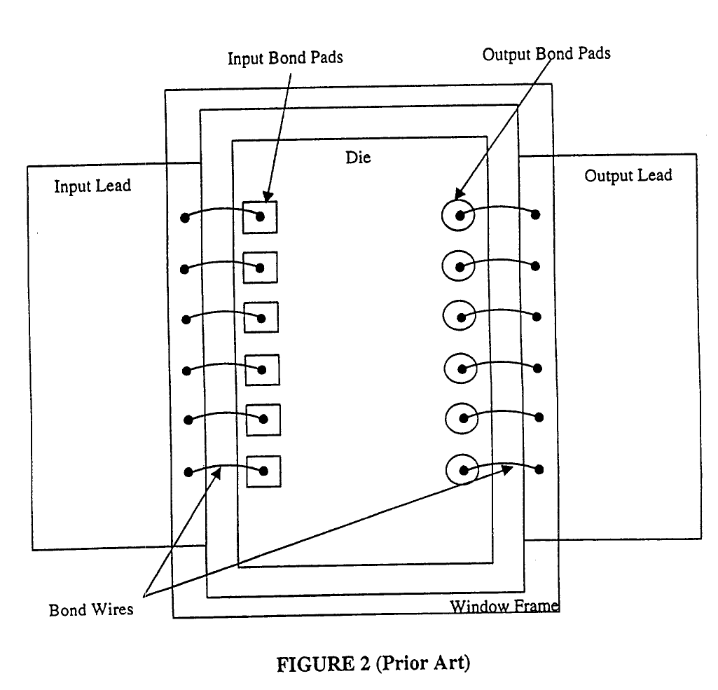

FIG. 2 is a bonding diagram of a typical packaged device. The typical packaged device includes a transistor die. The transistor die includes a multitude of input and output bond pads that are wire-bonded to input and output connections, respectively. The input and output connections are relatively wide single leads that feed current to and from the transistor die of the device. However, whenever circuit 100 is operating at high frequency there is typically a higher current density towards the outside edges of the wide single leads. Such an occurrence results in an unbalanced current feed to and from device 140. Ideally, the current density to and from device 140 should be evenly distributed across the input and output connections.

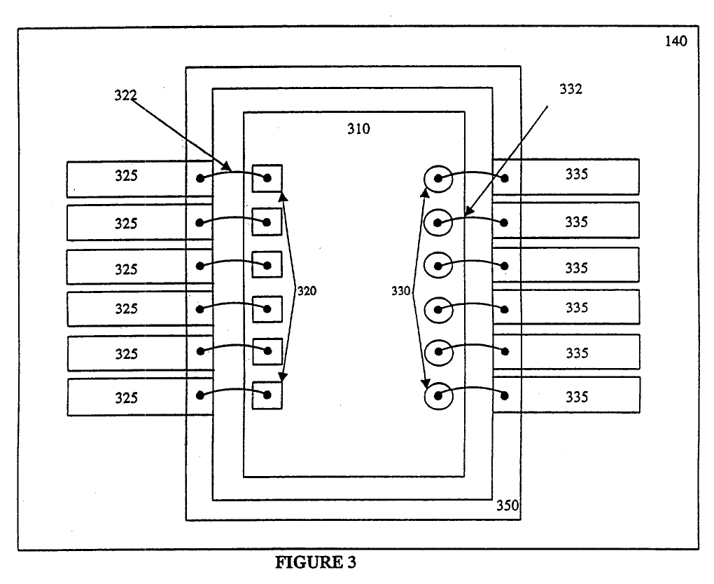

FIG. 3 is a bonding diagram of one embodiment of packaged device 140. Packaged device 140 includes transistor die 310 and window frame 350. According to one embodiment, window frame 350 is a ceramic window frame. However in other embodiments, window frame 350 may be comprised of other insulating materials (e.g., injection molded plastic). Transistor die 310 includes a plurality of transistor cells (not shown). The transistor gate contacts of the cells within die 310 are supplied current from input connections 325 that are wire-bonded to input bond pads 320 by bond-wires 322. According to one embodiment, input connections 325 are segmented such that each portion feeds a relatively equivalent magnitude current to die 310. According to a further embodiment, each of the bond pads 320 at die 310 are bonded to a separate input connection 325.

The transistor drain contacts of transistor cells within die 310 supply current to output connections 335 that are wire-bonded to output bond pads 330 by bond-wires 332. Similar to input connections 325, output connections 335 are segmented such that each portion carries a relatively equivalent magnitude of current from die 310. In addition, each of the bond pads 330 are bonded to a separate input connection 335.

Connections 325 and 335 are transition connections between the portions of circuit 100 that are external to device 140 to bond wires internal to device 140. According to one embodiment, connections 325 and 335 are leads integral to the package. However, connections 325 and 335 may comprise contact pads in other embodiments. One of ordinary skill in the art will appreciate that the configuration of transistor die 310 may be varied such that input connections 325 are segmented connections and the output connection is a single wide connection, or input connections 325 is a single-wide connection and the output connections are segmented connections.

According to a further embodiment, connections 325 and 335 may be coupled to the respective bond pads in such a manner as to improve the thermal balance of die 310. In a typical transistor die under high-power pulsed modulation (e.g., FIG. 2), the transistor cells at the outer edges of the die may become exceptionally hot due to the higher current density received from the outside edges of the single wide trace. However, in the present invention, a more uniform temperature distribution may be achieved utilizing the segmented connections.

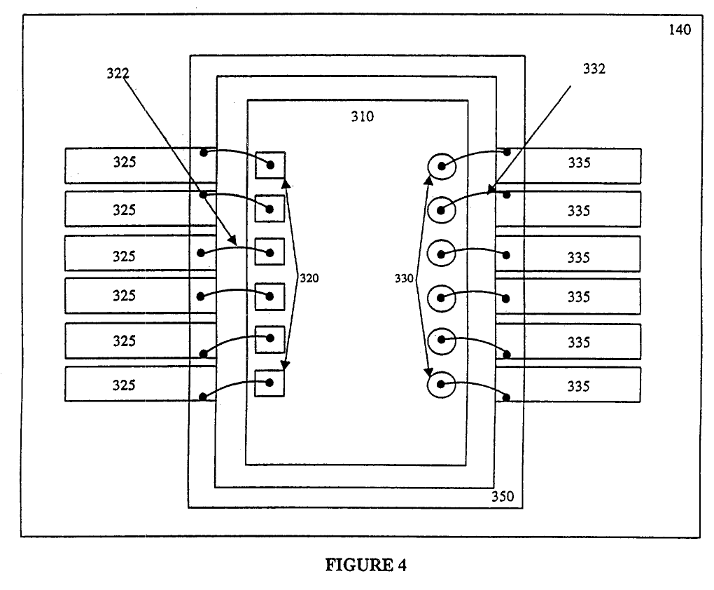

In a typical transistor die under high-power continuous wave (CW) operation, the transistor cells at the edges of the die may become exceptionally cool due to the ease of heat removal at the perimeter of the die. FIG. 4 is a bonding diagram for another embodiment of packaged device 140. Bonding wires leading from the top two bond pads 320 and 330 are connected at the top portion of connections 325 and 335, respectively.

In addition, bonding wires leading from the middle two bond pads 320 and 330 are connected at the center portion of connections 325 and 335, respectively. Further, bonding wires leading from the bottom two bond pads 320 and 330 are connected at the bottom portion of connections 325 and 335, respectively. The placement of bond-wires at the edge of the outside connections enables an incremental increase of current supply to the outer connections. As a result, the temperature across die 310 is distributed uniformly throughout the active area.

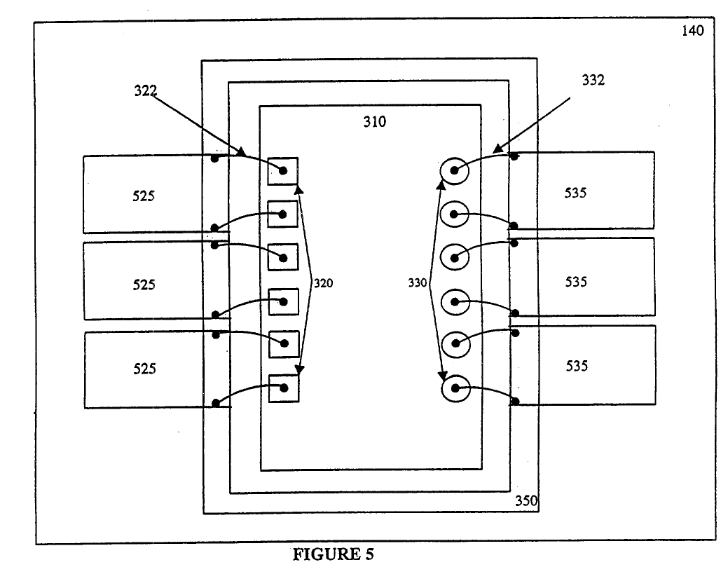

FIG. 5 is a bond diagram for another embodiment of packaged device 140. In this embodiment, input connections 525 are segmented such that each portion feeds a relatively equivalent current to die 310. According to a further embodiment, each input connection 525 supplies current to two bond pads 320. Also, input connections 525 are situated so that bond wires 322 are connected at the edges of input connections 525. Similarly, output connections 535 are segmented such that each portion carries an equivalent magnitude of current from die 310. In addition, each output connection 535 carries current from two bond pads 330.

Further, output connections 535 are situated so that bond wires 332 are connected at the outside edges of output connections 535. Bonding the input and output bond-wires at the edge of the respective connections enables the magnitude of current supplied to die 310 to be maximized. One of ordinary skill in the art will appreciate that in other applications connections 525 and 535 may each be connected to more than two bond pads. In such other embodiments, the bond-wires connected to the bond pads may be uniformly distributed about each connection.

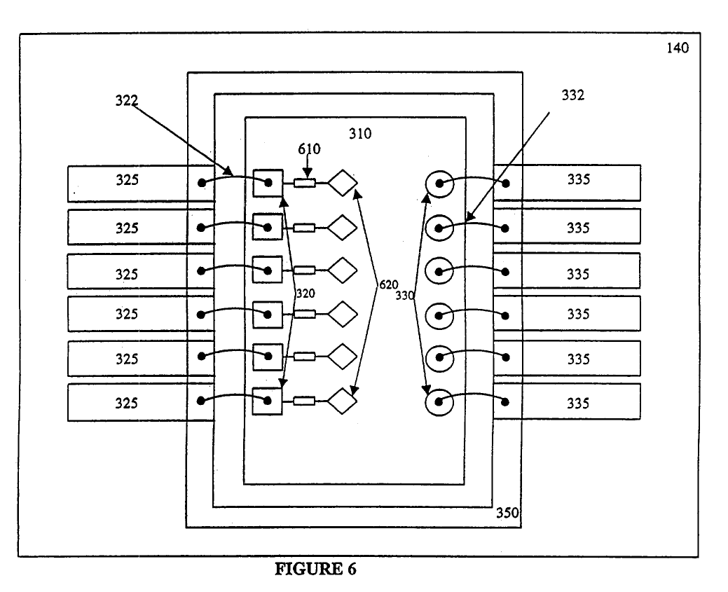

FIG. 6 is a bond diagram of another embodiment of power amplifying device 140. In this embodiment, die 310 includes a resistor network coupled in series with input connections 322. In one embodiment, the resistor network includes a resistor 610 coupled between each input bond pad 320 and a gate contact 620. The resistors 610 of resistor network further equalize the current paths into die 310 so that the current will not prefer one bond pad 320 of the die to the others. According to one embodiment, each resistor 610 has a 1.5 Ω resistance. Nevertheless, one of ordinary skill in the art will appreciate that other values for resistors 610 may be used. In addition, one of ordinary skill in the art will recognize that resistors 610 may be coupled between output bond pads 330 and drain contacts of die 310.

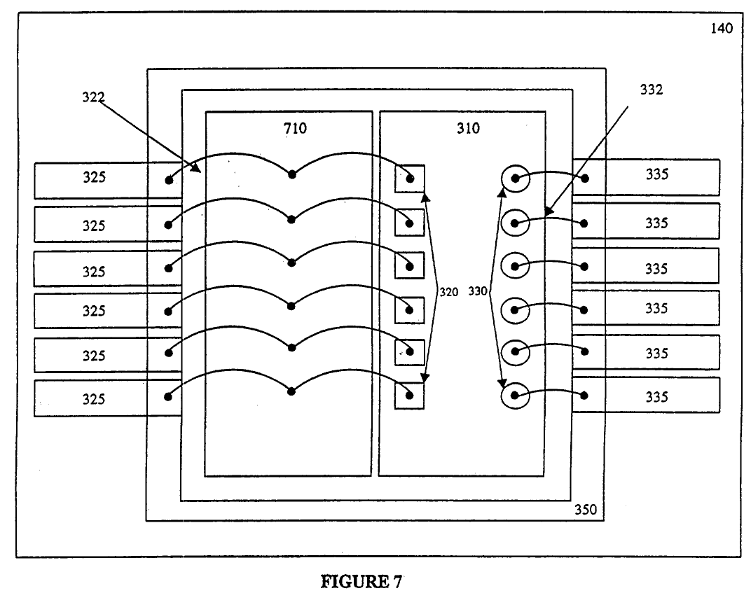

FIG. 7 is a bond diagram of another embodiment of power amplifying device 140. In such an embodiment, device 140 includes a component 710 connected to transistor die 310. According to one embodiment, component 710 is a capacitor. However in other embodiments, component 710 may comprise a resistor, inductor or any other type of circuit component. Component 710 is supplied current from-input connections 325 that are wire-bonded to component 710.

Component 710 is also wire-bonded to input bond pads 320 within die 310. Output bond pads 330 within die 310 are wire-bonded to output connections 335 by bond-wires 332. One of ordinary skill in the art will appreciate that additional components 710 may be included within amplifying device 140. For example, an additional component 710 may be wire-bonded between die 310 and output connections 335.

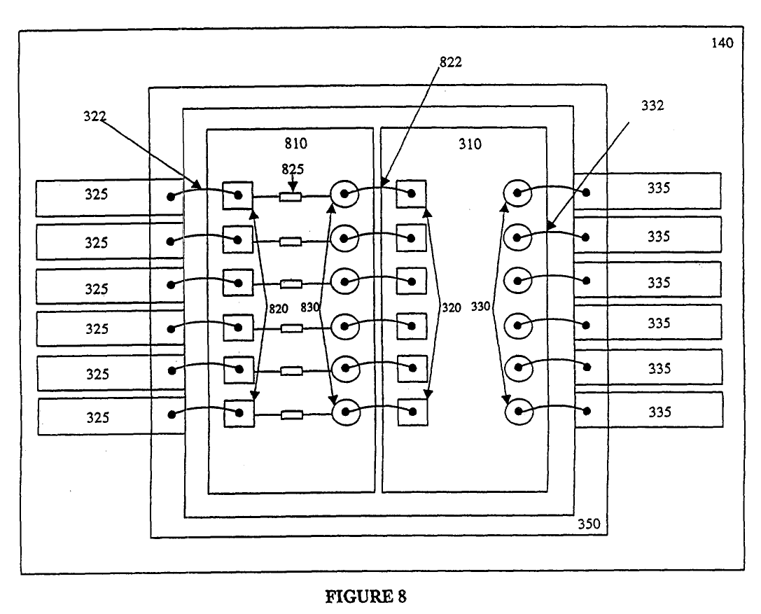

FIG. 8 is a bond diagram of another embodiment of power amplifying device 140. In such an embodiment, device 140 includes a component 810 connected to transistor die 310. According to one embodiment, component 810 includes input bond pads 820 and output bond pads 830. Input bond pads 820 are wire-bonded to input leads 325 via wire bonds 322. Component 810 also includes a resistor network. The resistor network includes a resistor 825 coupled between input bond pads 820 and output bond pads 830. Output bond pads 830 within component 810 are wire bonded to input bond pads 320 within die 310 via wire bonds 822. Output bond pads 330 are wire-bonded to output leads 335 via wire bonds 335. As described above, resistors 825 further equalize the current paths into die 310 so that the current will not prefer one bond pad 320 of the die to the others.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as the invention.

What is claimed is:

1. A solid state power amplifying device comprising:
a die;
a first output bond pad mounted on the die;
a first output lead; and
a first bond wire selectively positioned on the first output lead to control the magnitude of current carried from the first output bond pad.

2. The amplifying device of claim 1 further comprising:
a second output bond pad mounted on the die;
a second output lead; and
a second bond wire selectively positioned on the second output lead to control the magnitude of current carried from the second output bond pad.

3. The amplifying device of claim 2 wherein an equivalent magnitude of current is supplied to the first and second output bond pads.

4. The amplifying device of claim 2 further comprising:
a first output terminal mounted on the die;
a second output terminal mounted on the die;
a first resistor on the die coupled between the first output bond pad and the first output terminal; and
a second resistor on the die coupled between the second output bond pad and the second output terminal.

5. The amplifying device of claim 2 further comprising:
a third output bond pad mounted on the die;
a third output lead; and
a third bond wire selectively positioned on the third output lead to control the magnitude of current carried from the third output bond pad;
wherein an equivalent magnitude of current is supplied to the first, second and third output bond pads on the die.

6. The amplifying device of claim 5 wherein the first bond wire is positioned at the outside edge of the first output lead, the second bond wire is positioned at the center of the second output lead and the third bond wire is positioned at the outside edge of the third output lead.

7. The amplifying device of claim 2 wherein the first bond wire is positioned at an edge of the first output lead and the second bond wire is positioned at an edge of the second output lead.

8. The amplifying device of claim 1 wherein the amplifying device is a laterally diffused metal oxide semiconductor field effect transistor (LDMOS FET).

9. The amplifying device of claim 1 wherein the amplifying device is a vertically diffused metal oxide semiconductor field effect transistor (DMOS FET).

10. The amplifying device of claim 1 wherein the amplifying device is a metal semiconductor field effect transistor (MES FET).

11. The amplifying device of claim 1 wherein the amplifying device is a pseudomorphic high electron mobility field effect transistor (PHEMT FET).

12. The amplifying device of claim 1 wherein the amplifying device is a bipolar junction transistor (BJT).

13. The amplifying device of claim 1 wherein the amplifying device is a heterojunction bipolar transistor (HBT).

14. A device comprising:
a circuit component;
a first output bond pad mounted on the circuit component;
a second output bond pad mounted on the circuit component;
a first output lead;
a second output lead;
a first bond wire selectively positioned on the first output lead to control the magnitude of current carried from the first output bond pad; and
a second bond wire selectively positioned on the second output lead to control the magnitude of current carried from the second output bond pad;
wherein an equivalent magnitude of current is supplied from the first and second output bond pads on the circuit component.

15. The device of claim 14 further comprising:
a first resistor on the circuit component coupled between the first output bond pad and a first input bond pad; and
a second resistor on the circuit component coupled between the second output bond pad and a second input bond pad.

16. The device of claim 14 further comprising:
a die;
a first output bond pad mounted on the die;
a second output bond pad mounted on the die;
a third bond wire coupled to a first input bond pad on the circuit component; and
a fourth bond wire coupled to a second input bond pad on the circuit component.

17. A solid state power amplifying device comprising:
a die;
a first output bond pad mounted on the die;
a second output bond pad mounted on the die;
a first output lead;
a first bond wire coupled between the first output bond pad and a first edge of the first output lead; and
a second bond wire coupled between the second output bond pad and a second edge of the first output lead, wherein an equivalent magnitude of current is supplied to the first and second output bond pads.

18. The amplifying device of claim 17 further comprising:
a third output bond pad mounted on the die; and
a third bond wire coupled between the third output bond pad and the first output lead between the first and second bond wires.

19. The amplifying device of claim 17 further comprising:
a third output bond pad mounted on the die;
a fourth output bond pad mounted on the die;
a second output lead;
a third bond wire coupled between the third output bond pad and a first edge of the second output lead; and
a fourth bond wire coupled between the fourth output bond pad and a second edge of the second output lead, wherein an equivalent magnitude of current is supplied to the third and fourth output bond pads.
